(19) United States
(12) Patent Application Publication
(10) Pub. No.: US 2014/0138598 A1
(43) Pub. Date: May 22, 2014

(54) NONVOLATILE MEMORY DEVICE

(71) Applicant: Kabushiki Kaisha Toshiba, Minato-ku (JP)

(72) Inventors: Takashi Haimoto, Mie-ken (JP); Reika Ichihara, Kanagawa-ken (JP); Yuuichiro Mitani, Kanagawa-ken (JP); Masato Koyama, Mie-ken (JP)

(73) Assignee: Kabushiki Kaisha Toshiba, Minato-ku (JP)

(21) Appl. No.: 14/026,301

(22) Filed: Sep. 13, 2013

(30) Foreign Application Priority Data
Nov. 20, 2012 (JP) 2012-254572

(51) Int. Cl. H01L 45/00

(52) U.S. Cl. CPC H01L 45/12
USPC 257/2

(57) ABSTRACT

According to one embodiment, nonvolatile memory device includes a semiconductor layer, a conductive layer and a resistance change layer. The semiconductor layer has an impurity concentration less than 1×10¹⁹ cm⁻³. The resistance change layer is provided between the semiconductor layer and the conductive layer. The resistance change layer includes a fixed charge. The resistance change layer is reversibly transitionable between a first state and a second state by at least one selected from a current supplied via the semiconductor layer and the conductive layer and a voltage applied via the semiconductor layer and the conductive layer. A resistance of the resistance change layer in the second state is higher than a resistance of the resistance change layer in the first state.

### CROSS-REFERENCE TO RELATED APPLICATIONS

This application is based upon and claims the benefit of priority from Japanese Patent Application No. 2012-254572, filed on Nov. 20, 2012; the entire contents of which are incorporated herein by reference.

### FIELD

Embodiments described herein relate generally to a nonvolatile memory device.

### BACKGROUND

The demand for nonvolatile memory devices that are small and have large bit densities is rapidly increasing. New memory has been proposed to surpass the limits of conventional bit density. For example, memory that uses a resistance change material having a low resistance state and a high resistance state has been proposed. Forming in which a relatively high voltage is applied to the elements is performed in a resistance change nonvolatile device as initialization for the operation of the resistance change. In the case where the voltage of the forming is high, there are cases where breakdown of the elements occurs; and there are cases where the reliability degrades. A new configuration having uniform characteristics for which a stable initialization at a low voltage is possible is desirable.

### BRIEF DESCRIPTION OF THE DRAWINGS

FIG. 1 is a schematic cross-sectional view showing a nonvolatile memory device according to a first embodiment;

FIG. 2 is a schematic perspective view showing the nonvolatile memory device according to the first embodiment;

FIG. 3A to FIG. 3C are graphs showing characteristics of the nonvolatile memory device;

FIG. 4 is a schematic cross-sectional view showing another nonvolatile memory device according to the first embodiment;

FIG. 5 is a schematic cross-sectional view showing a nonvolatile memory device according to a second embodiment;

FIG. 6A and FIG. 6B are graphs showing characteristics of the nonvolatile memory device;

FIG. 7 is a schematic cross-sectional view showing another nonvolatile memory device according to the second embodiment;

FIG. 8A and FIG. 8B are graphs showing characteristics of the nonvolatile memory device;

FIG. 9A and FIG. 9B are graphs showing characteristics of the nonvolatile memory device;

FIG. 10 is a graph showing characteristics of the nonvolatile memory device according to the embodiment;

FIG. 11 is a graph showing characteristics of the nonvolatile memory device according to the embodiment;

FIG. 12 is a graph showing characteristics of the nonvolatile memory device according to the embodiment;

FIG. 13 is a graph showing characteristics of the nonvolatile memory device according to the embodiment;

FIG. 14 is a schematic perspective view showing the nonvolatile memory device according to the fifth embodiment;

FIG. 15 is a schematic view showing the nonvolatile memory device according to the fifth embodiment;

FIG. 16 is schematic perspective view showing other nonvolatile memory devices according to the fifth embodiment;

FIG. 17 is schematic perspective view showing other nonvolatile memory devices according to the fifth embodiment.

### DETAILED DESCRIPTION

In general, according to one embodiment, a nonvolatile memory device includes a semiconductor layer, a conductive layer and a resistance change layer. The semiconductor layer has an impurity concentration less than 1×10¹⁹ cm⁻³. The resistance change layer is provided between the semiconductor layer and the conductive layer. The resistance change layer includes a fixed charge. The resistance change layer is reversibly transitionable between a first state and a second state by at least one selected from a current supplied via the semiconductor layer and the conductive layer and a voltage applied via the semiconductor layer and the conductive layer. A resistance of the resistance change layer in the second state is higher than a resistance of the resistance change layer in the first state.

According to another embodiment, a nonvolatile memory device includes a semiconductor layer, a conductive layer, a resistance change layer and an interface portion. The semiconductor layer has an impurity concentration less than 1×10¹⁹ cm⁻³. The resistance change layer is provided between the semiconductor layer and the conductive layer. The resistance change layer is reversibly transitionable between a first state and a second state by at least one selected from a current supplied via the semiconductor layer and the conductive layer and a voltage applied via the semiconductor layer and the conductive layer. The resistance of the resistance change layer in the second state is higher than a resistance of the resistance change layer in the first state. The interface portion is provided between the semiconductor layer and the resistance change layer. The interface portion includes a dipole.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

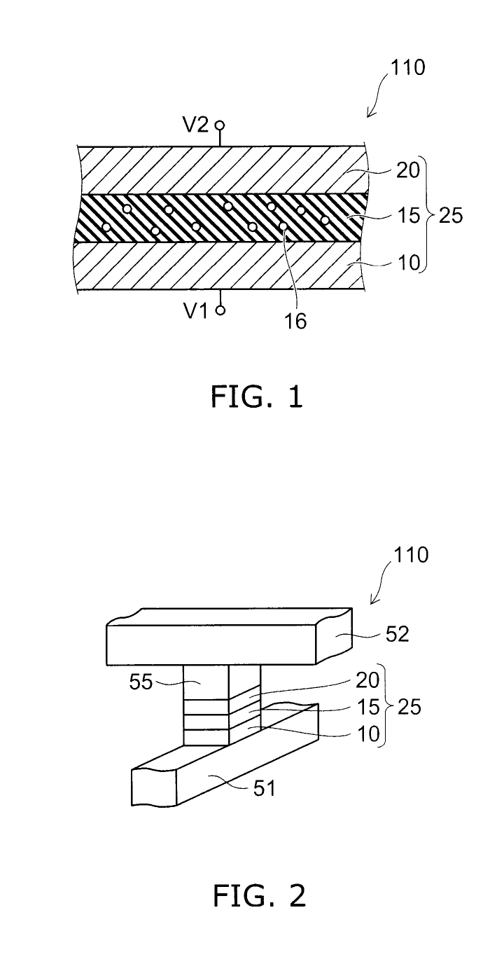

FIG. 1 is a schematic cross-sectional view showing a nonvolatile memory device according to a first embodiment.

As shown in FIG. 1, the nonvolatile memory device 110 according to the embodiment includes a semiconductor layer 10, a conductive layer 20, and a resistance change layer 15. The resistance change layer 15 is provided between the semiconductor layer 10 and the conductive layer 20. The semiconductor layer 10, the conductive layer 20, and the resistance change layer 15 are included in a memory unit 25.

The potential of the semiconductor layer 10 is taken as a first potential V1. The potential of the conductive layer 20 is taken as a second potential V2. The voltage (an externally-applied voltage Va) applied between the semiconductor layer 10 and the conductive layer 20 is the difference between the second potential V2 and the first potential V1. In the description hereinbelow, the first potential V1 is taken to be a reference potential.

The resistance change layer 15 is reversibly transitionable between a first state that has a low resistance and a second state that has a resistance that is higher than that in the first state by at least one selected from a current supplied via the semiconductor layer 10 and the conductive layer 20 and the voltage (the externally-applied voltage Va) applied via the semiconductor layer 10 and the conductive layer 20.

In the embodiment, the resistance change layer 15 includes a fixed charge 16. The fixed charge 16 is described below.

The semiconductor layer 10 includes, for example, polysilicon. A depletion layer is formable in at least a portion of the semiconductor layer 10 opposing the resistance change layer 15. The impurity concentration of the semiconductor layer 10 is set to be in a state in which the depletion layer is formable. The impurity concentration of the semiconductor layer 10 is, for example, less than 1×10¹⁹ cm⁻³. The impurity concentration of the semiconductor layer 10 is, for example, not less than 1×10¹⁵ cm⁻³. The depletion layer is not formed in the case where the impurity concentration of the semiconductor layer 10 is excessively high.

The conductive layer 20 includes, for example, a metal or an alloy. Also, a compound such as TiN, TaN, WN, NiSi, etc., may be used as the conductive layer 20.

The resistance change layer 15 may include, for example, an oxide including at least one selected from the group consisting of Hf, Ni, Ta, Ti, W, Cu, Nb, Mn, Fe, Zr, Al, Co, etc.

The thickness of the resistance change layer 15 is, for example, not less than 1 nm and not more than 300 nm. Downscaling is easy in the case where the thickness of the resistance change layer 15 is thin. In the case where the thickness of the resistance change layer 15 is too thin, for example, it is difficult to obtain a homogeneous film. It is more favorable for the thickness of the resistance change layer 15 to be not less than 2 nm and not more than 50 nm.

FIG. 2 is a schematic perspective view showing the nonvolatile memory device according to the first embodiment.

As shown in FIG. 2, the nonvolatile memory device 110 according to the embodiment may further include a first interconnect 51, a second interconnect 52, and a rectifying unit 55. The first interconnect 51 extends in a first direction. The second interconnect 52 extends in a second direction. The second direction is non-parallel to the first direction. The memory unit 25 and the rectifying unit 55 are disposed between the first interconnect 51 and the second interconnect 52.

In the example, the memory unit 25 is disposed between the first interconnect 51 and the rectifying unit 55. However, the memory unit 25 may be disposed between the second interconnect 52 and the rectifying unit 55. The rectifying unit 55 may include, for example, a diode.

The first interconnect 51 and the second interconnect 52 may include, for example, a metal such as tungsten, etc.

The first interconnect 51, the second interconnect 52, and the rectifying unit 55 may be further provided in each of the embodiments described below, even when not shown.

Hereinbelow, the case where the semiconductor layer 10 is the n type is described as an example. The semiconductor layer 10 includes, for example, n⁺ polysilicon. A depletion layer is formed in the semiconductor layer 10 in the case where the n-type impurity concentration of the semiconductor layer 10 is low. In the case where depletion layer is formed in the semiconductor layer 10, the electric field applied to the resistance change layer 15 can be modulated by controlling a flat band voltage Vfb of the memory unit 25 (the semiconductor layer 10, the resistance change layer 15, and the conductive layer 20). Examples of the control of the flat band voltage Vfb are described below.

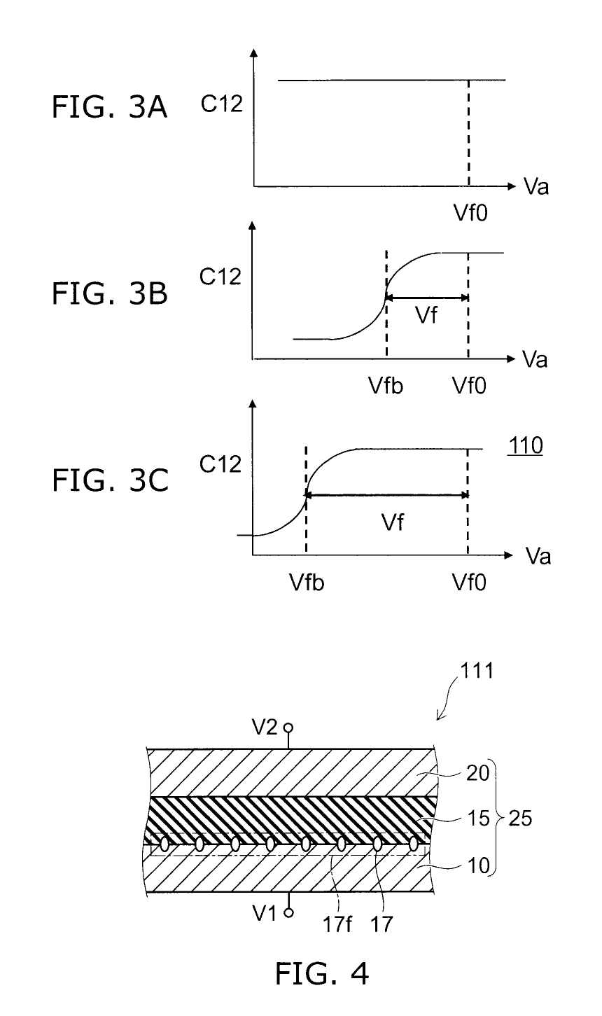

FIG. 3A to FIG. 3C are graphs showing characteristics of the nonvolatile memory device.

These drawings show the change of an electrostatic capacitance C12 between the semiconductor layer 10 and the conductive layer 20 when the externally-applied voltage Va is applied between the semiconductor layer 10 and the conductive layer 20. The horizontal axis is the externally-applied voltage Va; and the vertical axis is the electrostatic capacitance C12. FIG. 3A shows the characteristic of an element in which the depletion layer is not formed. FIG. 3B shows the characteristic of an element in which the depletion layer is formed and the flat band voltage Vfb is not controlled appropriately. FIG. 3C shows the characteristic of an element in which the depletion layer is formed and the flat band voltage Vfb is controlled appropriately. In the case where the impurity concentration of the semiconductor layer 10 is high, the depletion layer is not formed; and in the case where the impurity concentration of the semiconductor layer 10 is low, the depletion layer is formed.

In the case where the depletion layer is not formed as shown in FIG. 3A, the C-V characteristic is flat. In such a case, a voltage that is a constant proportion of the externally-applied voltage Va is applied to the resistance change layer 15 regardless of the value of the externally-applied voltage Va. In such a case, the ratio of the voltage applied to the resistance change layer 15 to the externally-applied voltage Va is constant regardless of the flat band voltage Vfb.

In the case where the depletion layer is formed as shown in FIG. 3B and FIG. 3C, the C-V characteristic is not flat. In the example, the electrostatic capacitance C12 is small when the externally-applied voltage Va is small; and the electrostatic capacitance C12 increases when the externally-applied voltage Va exceeds a threshold. Further, the electrostatic capacitance C12 becomes large and becomes substantially constant when the externally-applied voltage Va becomes large. Thus, in an element in which the depletion layer is formed, the electrostatic capacitance C12 changes according to the value of the externally-applied voltage Va.

Compared to the case (FIG. 3B) where the flat band voltage Vfb is not appropriately controlled, the C-V characteristic can be caused to shift toward the negative side by appropriately controlling the flat band voltage Vfb as shown in FIG. 3C.

For convenience, causing the C-V characteristic to shift toward the negative side is referred to as a shift of the flat band voltage Vfb in the negative direction or a decrease of the flat band voltage Vfb. Also, for convenience, causing the C-V characteristic to shift toward the positive side is referred to as a shift of the flat band voltage Vfb in the positive direction or an increase of the flat band voltage Vfb.

For example, the portion of the externally-applied voltage Va applied to the depletion layer of the semiconductor layer 10 is the flat band voltage Vfb. In the nonvolatile memory device 110, a forming voltage Vf0 for forming is applied between the semiconductor layer 10 and the conductive layer 20. A portion (Vf0−Vfb) of the forming voltage Vf0 is applied to the resistance change layer 15.

In the case where the flat band voltage Vfb is not controlled appropriately as shown in FIG. 3B, an effective forming voltage Vf applied to the resistance change layer 15 is small.

Conversely, in the case where the flat band voltage Vfb is controlled appropriately (in the case where the flat band voltage Vfb shifts in the negative direction) as shown in FIG. 3C, the effective forming voltage Vf applied to the resistance change layer 15 is larger than that of the case of FIG. 3B.

Such characteristics are utilized in the embodiment. In other words, the depletion layer is formed in the semiconductor layer 10; and the flat band voltage Vfb is appropriately controlled. Thereby, the decrease of the effective forming voltage Vf applied to the resistance change layer 15 is suppressed. Thereby, the forming voltage Vf0 can be reduced while suppressing the fluctuation of the forming voltage. Thereby, a nonvolatile memory device having easy manufacturing, uniform characteristics, and high reliability can be provided.

In a resistance change nonvolatile memory device, forming is performed as initialization for the operation of the resistance change. A relatively high voltage is applied to the element in the forming. In the case where the voltage of the forming is high, there are cases where breakdown of the element occurs; and there are cases where the reliability degrades. It is desirable to reduce the forming voltage Vf0.

It is considered that current paths are linked randomly in the inner-plane direction and the thickness direction in the resistance change layer 15 by the forming. For example, the current paths are formed when defects that occur randomly inside the resistance change layer 15 are linked in the layer thickness direction. It is considered that a phenomenon that is similar to, for example, the TDDB (Time Dependent Dielectric Breakdown) phenomenon occurs when the current paths are formed by the forming. It is considered that, for example, a percolation model is applicable to the phenomenon occurring due to the forming.

The forming voltage Vf0 can be reduced by reducing the thickness of the resistance change layer 15. However, in the case where a percolation model is obeyed, the fluctuation of the forming voltage increases in the case where the thickness of the resistance change layer 15 is reduced.

A configuration that reduces the forming voltage Vf0 without increasing the fluctuation of the characteristics after the forming is desired.

On the other hand, for example, a semiconductor doped with an impurity (e.g., polysilicon doped with an impurity) may be used as the conductive layer connected to the resistance change layer 15. In such a case, an interface layer is formed between the resistance change layer and the semiconductor doped with the impurity; and the characteristics after the forming are improved.

In the embodiment, the semiconductor layer 10 is used as a conductive layer connected to one side of the resistance change layer 15 and is configured such that the depletion layer is formed. Thereby, the depletion layer functions as a series resistance; the excessive current due to the forming voltage application is limited; and it is possible to suppress the breakdown of the element.

Also, in the embodiment, the forming voltage Vf0 is reduced by appropriately controlling the flat band voltage Vfb when using the semiconductor layer 10 that is configured such that the depletion layer is formed.

In other words, as described in regard to FIG. 3B and FIG. 3C, the semiconductor layer 10 is the n type; and the positive voltage (the externally-applied voltage Va being positive) is applied to the conductive layer 20. In such a case, the forming voltage Vf0 can be lower in the state shown in FIG. 3C than in the state shown in FIG. 3B.

In the embodiment, even for the configuration in which the depletion layer is formed in the semiconductor layer 10, the increase of the forming voltage Vf0 can be suppressed without increasing the fluctuation of the forming voltage because the thickness of the resistance change layer 15 is not reduced. In other words, low fluctuation can be maintained; and the forming voltage Vf0 can be reduced.

An example of a configuration for appropriately controlling the flat band voltage Vfb will now be described.

For example, the flat band voltage Vfb can be reduced by at least one selected from reducing the work function of the conductive layer 20 and increasing the work function of the semiconductor layer 10.

For example, to reduce the work function of the conductive layer 20, a metal (including alloys) having a small work function is used as the conductive layer 20. Examples of such a metal include Ti, Al, Ta, etc.

For example, in the case where a compound is used as the conductive layer 20, the composition is set to be such that the work function is small. A work function φ depends on an electronegativity χ of the substance. The work function φ is large when the electronegativity χ is large. For example, for a compound MₘXₙ (M being a first chemical element and X being a second chemical element), the electronegativity of the first chemical element M is taken as χM; and the electronegativity of the second chemical element X is taken as χₓ. The electronegativity χ of the compound MₙXₙ is represented by

χ=(χM^{m}χXⁿ)^{(m+n)}.

For example, the electronegativities χM and χX and the composition ratios m and n of the compound MₘXₙ are set such that the electronegativity χ of the compound MₘXₙ is small.

For example, in the case where TiN is used as the conductive layer 20, the work function φ increases when the proportion of N (nitrogen) is increased. The work function φ decreases when the proportion of Ti (titanium) is increased.

For example, in the case where the semiconductor layer 10 is the n type, the impurity concentration is set to be low. Thereby, the work function of the semiconductor layer 10 is increased.

By such a method, at least one selected from reducing the work function of the conductive layer 20 and increasing the work function of the semiconductor layer 10 is performed. Thereby, the flat band voltage Vfb can be reduced.

Further, the C-V characteristic can be shifted by disposing the fixed charge 16 inside the resistance change layer 15.

For example, a positive fixed charge 16 is disposed inside the resistance change layer 15. For example, aluminum (Al) may be used as the positive fixed charge 16. Thereby, the C-V characteristic can be shifted in the negative direction.

FIG. 4 is a schematic cross-sectional view showing another nonvolatile memory device according to the first embodiment.

As shown in FIG. 4, the memory unit 25 (the semiconductor layer 10, the conductive layer 20, and the resistance change layer 15) are provided also in the nonvolatile memory device 111 according to the embodiment. The configuration described in regard to the nonvolatile memory device 110 is applicable to the semiconductor layer 10, the conductive layer 20, and the resistance change layer 15. Portions of the nonvolatile memory device 111 that are different from those of the nonvolatile memory device 110 will now be described.

As shown in FIG. 4, the nonvolatile memory device 111 further includes an interface portion 17f that includes a dipole 17 and is provided between the semiconductor layer 10 and the resistance change layer 15. The interface portion 17f may have a continuous film-like configuration or a discontinuous island configuration. Because the interface portion 17f is provided between the semiconductor layer 10 and the resistance change layer 15, the dipole 17 of the interface portion 17f is disposed at the interface between the semiconductor layer 10 and the resistance change layer 15. The dipole 17 may be considered to be a portion of the semiconductor layer 10 and may be considered to be a portion of the resistance change layer 15.

Thus, the C-V characteristic, i.e., the flat band voltage Vfb, can be controlled by further providing the interface portion 17f including the dipole 17 between the semiconductor layer 10 and the resistance change layer 15.

For example, the interface portion 17f may include at least one selected from hafnium oxide (HfOₓ), aluminum oxide (AlOₓ), and magnesium oxide (MgOₓ). Thereby, the C-V characteristic can be shifted in the negative direction.

In such a case, the semiconductor layer 10 is the n type and is in a state in which the depletion layer is formable. For example, n⁺ polysilicon is used as the semiconductor layer 10. Then, the forming is performed by applying a positive voltage to the conductive layer 20. Thereby, the decrease of the effective forming voltage Vf applied to the resistance change layer 15 is suppressed.

The dipole 17 (i.e., the interface portion 17f) recited above can be formed by, for example, causing a material including the chemical element recited above to contact the variable resistance film and by, for example, diffusion by heating.

In the embodiment, the semiconductor layer 10 is the n type; and the depletion layer is formed. Then, the forming is performed by applying the positive voltage to the conductive layer 20. In other words, the potential of the conductive layer 20 is set to be higher than the potential of the semiconductor layer 10 when forming. Such forming is performed after shifting the flat band voltage Vfb in the negative direction.

To cause the shift in the negative direction, for example, a positive fixed charge 16 (e.g., Al) is disposed in the resistance change layer 15. The fixed charge 16a may include a lanthanoid. Namely, the fixed charge 16a may include at least one selected from the group consisting of La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium).

The chemical element recited above is diffused into the resistance change layer 15 by, for example, causing the chemical element recited above to contact the resistance change layer 15 and by, for example, thermal diffusion by heating. Thereby, the fixed charge 16a recited above can be disposed inside the resistance change layer 15.

To cause the shift in the negative direction, for example, the interface portion 17f including the prescribed dipole 17 is provided. Specifically, the interface portion 17f including at least one selected from hafnium oxide (HfOₓ), aluminum oxide (AlOₓ), magnesium oxide (MgOₓ), launthanum oxide (LaOₓ), cerium oxide (CeOₓ), praseodymium oxide (PrOₓ), neodymium oxide (NdOₓ), promethium oxide (PmOₓ), samarium oxide(SmOₓ), europium oxide (EuOₓ), gadolinium oxide (GdOₓ), terbium oxide (TbOₓ), dysprosium oxide (DyOₓ), holmium oxide(HoOₓ), erbium oxide (ErOₓ), thulium oxide (TmOₓ), ytterbium oxide (YbOₓ), and lutetium oxide (LuOₓ) is provided.

The work function of the semiconductor layer 10 and the work function of the conductive layer 20 may be set to cause the shift in the negative direction.

According to the embodiment, a nonvolatile memory device having uniform characteristics for which a stable initialization at a low voltage is possible can be provided.

### Second Embodiment

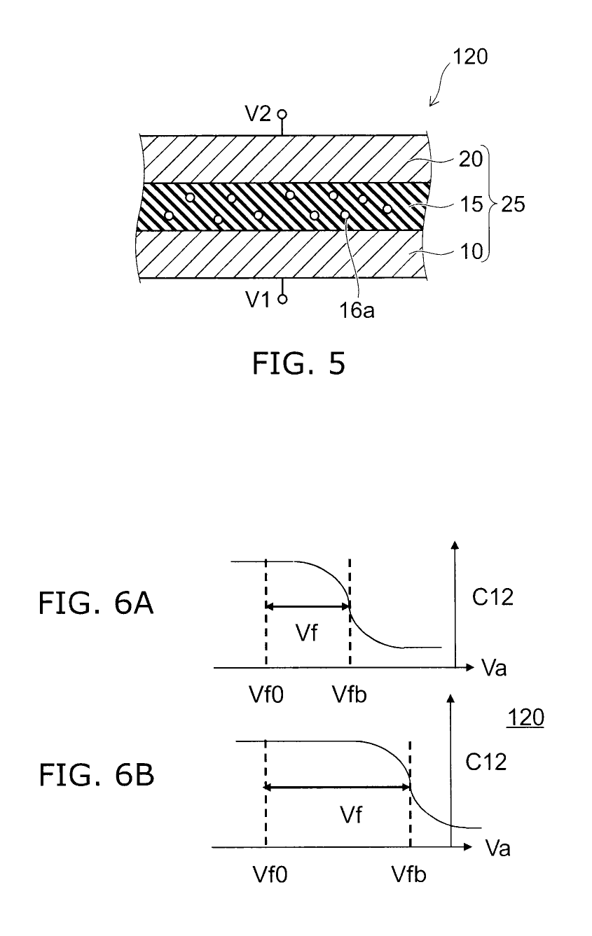

FIG. 5 is a schematic cross-sectional view showing a nonvolatile memory device according to a second embodiment.

As shown in FIG. 5, the memory unit 25 (the semiconductor layer 10, the conductive layer 20, and the resistance change layer 15) are provided also in the nonvolatile memory device 120 according to the embodiment. The configuration described in regard to the nonvolatile memory device 110 is applicable to the semiconductor layer 10, the conductive layer 20, and the resistance change layer 15. In the nonvolatile memory device 120, the resistance change layer 15 includes a fixed charge 16a. Portions of the nonvolatile memory device 120 that are different from those of the nonvolatile memory device 110 will now be described.

In the nonvolatile memory device 120, a negative fixed charge is used as the fixed charge 16a disposed in the resistance change layer 15. For example, the fixed charge 16a includes nitrogen (N). For example, the fixed charge 16a including nitrogen is formed in the resistance change layer 15 by nitriding the resistance change layer 15.

Thus, the C-V characteristic is shifted in the positive direction by disposing the negative fixed charge 16a inside the resistance change layer 15. In other words, the flat band voltage Vfb is shifted in the positive direction.

In such a case, the semiconductor layer 10 is the p type; and the depletion layer is formable. Then, the forming is performed by applying a negative voltage to the conductive layer 20. Thereby, the decrease of the effective forming voltage Vf applied to the resistance change layer 15 is suppressed.

FIG. 6A and FIG. 6B are graphs showing characteristics of the nonvolatile memory device.

These drawings show the change of the electrostatic capacitance C12 between the semiconductor layer 10 and the conductive layer 20 in the case where the semiconductor layer 10 is the p type and when the externally-applied voltage Va is applied between the semiconductor layer 10 and the conductive layer 20. FIG. 6A shows the characteristic of an element in which the depletion layer is formed and the flat band voltage Vfb is not controlled appropriately. FIG. 6B shows the characteristic of an element in which the depletion layer is formed and the flat band voltage Vfb is controlled appropriately.

As shown in FIG. 6A, compared to the case (FIG. 6B) in which the flat band voltage Vfb is not controlled appropriately, the C-V characteristic can be caused to shift toward the positive side by appropriately controlling the flat band voltage Vfb.

For example, the portion of the externally-applied voltage Va applied to the depletion layer of the semiconductor layer 10 is the flat band voltage Vfb. In the nonvolatile memory device 120, the forming voltage Vf0 for forming is applied between the semiconductor layer 10 and the conductive layer 20. A portion (Vf0−Vfb) of the forming voltage Vf0 is applied to the resistance change layer 15.

As shown in FIG. 6A, the effective forming voltage Vf applied to the resistance change layer 15 is small in the case where the flat band voltage Vfb is not controlled appropriately.

Conversely, as shown in FIG. 6B, in the case where the flat band voltage Vfb is controlled appropriately (in the case where the flat band voltage Vfb shifts in the positive direction), the effective forming voltage Vf applied to the resistance change layer 15 is larger than that of the case of FIG. 6A.

Such characteristics are utilized in the embodiment. In other words, the depletion layer is formed in the semiconductor layer 10; and the flat band voltage Vfb is appropriately controlled. Thereby, the decrease of the effective forming voltage Vf applied to the resistance change layer 15 is suppressed.

Thus, in the case where the forming is performed by applying the negative voltage to the conductive layer 20, the semiconductor layer 10 is the p type; the depletion layer is formable; and the negative fixed charge 16a is disposed inside the resistance change layer 15. Thereby, the flat band voltage Vfb is shifted in the positive direction. Thereby, the decrease of the effective forming voltage Vf applied to the resistance change layer 15 is suppressed. Thereby, the forming voltage Vf0 can be reduced while suppressing the fluctuation of the forming voltage. Thereby, a nonvolatile memory device having easy manufacturing, uniform characteristics, and high reliability can be provided.

In the example, at least one selected from lanthanum oxide (LaOₓ) and yttrium oxide (YOₓ) is used as the dipole. In other words, the interface portion 17f includes at least one selected from lanthanum oxide and yttrium oxide. Thereby, the C-V characteristic can be shifted in the positive direction.

In such a case, the semiconductor layer 10 is the p type and is in a state in which the depletion layer is formable. Then, the forming is performed by applying a negative voltage to the conductive layer 20. Thereby, the decrease of the effective forming voltage Vf applied to the resistance change layer 15 is suppressed. Thereby, the forming voltage Vf0 can be reduced while suppressing the fluctuation of the forming voltage.

The dipole 17a (i.e., the interface portion 17f) recited above can be formed by, for example, causing a material including the chemical element recited above to contact the variable resistance film and by, for example, diffusion by heating.

In the embodiment, the flat band voltage Vfb also can be shifted in the positive direction by correcting the work function of the semiconductor layer 10 and the work function of the conductive layer 20.

In the embodiment, the semiconductor layer 10 is the p type; and the depletion layer is formed. Then, the forming is performed by applying the negative voltage to the conductive layer 20. The potential of the conductive layer 20 is caused to be lower than the potential of the semiconductor layer 10 when forming. Such forming is performed after shifting the flat band voltage Vfb in the positive direction.

To cause the shift in the positive direction, for example, a negative fixed charge 16 (e.g., nitrogen, etc.) is disposed in the resistance change layer 15.

The work function of the semiconductor layer 10 and the work function of the conductive layer 20 may be set to cause the shift in the positive direction.

According to the embodiment, a nonvolatile memory device having uniform characteristics for which a stable initialization at a low voltage is possible can be provided.

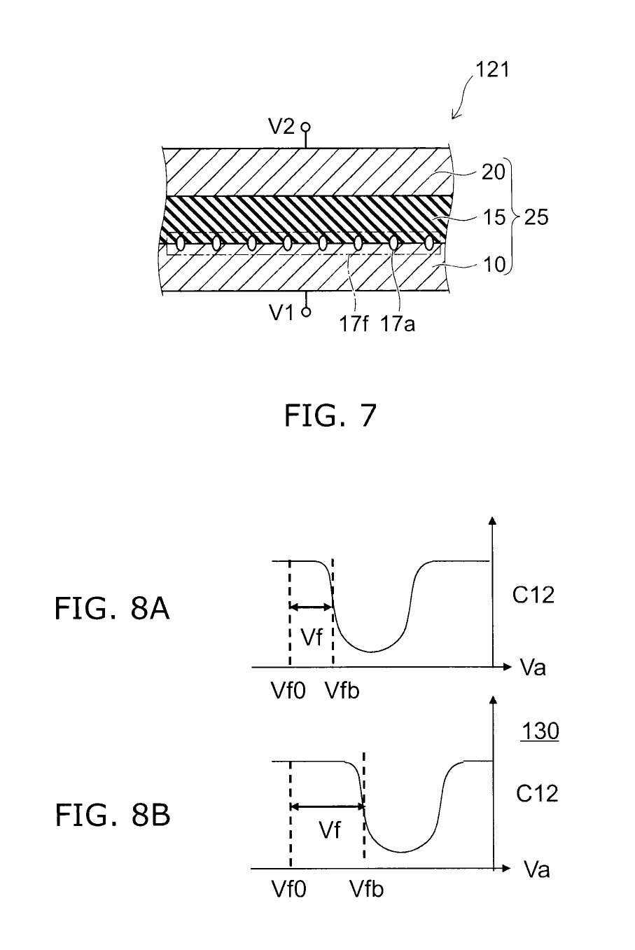

FIG. 7 is a schematic cross-sectional view showing another nonvolatile memory device according to the second embodiment.

As shown in FIG. 7, the memory unit 25 (the semiconductor layer 10, the conductive layer 20, and the resistance change layer 15) are provided also in the nonvolatile memory device 121 according to the embodiment.

### Third Embodiment

The memory unit 25 (the semiconductor layer 10, the conductive layer 20, and the resistance change layer 15) are provided also in a nonvolatile memory device according to the embodiment. In the embodiment, the semiconductor layer 10 may be the n type. In the embodiment, the configuration described in regard to the nonvolatile memory device 110 is applicable to the semiconductor layer 10, the conductive layer 20, and the resistance change layer 15.

FIG. 8A and FIG. 8B are graphs showing characteristics of the nonvolatile memory device.

FIG. 8A shows the characteristic of an element in which the depletion layer is formed and the flat band voltage Vfb is not controlled appropriately. FIG. 8B shows the characteristic of an element in which the depletion layer is formed and the flat band voltage Vfb is controlled appropriately. FIG. 8B corresponds to the nonvolatile memory device 130 (of which the configuration is not shown) according to the embodiment.

In the example as shown in FIG. 8A and FIG. 8B, the electrostatic capacitance C12 changes in a valley-like configuration as the externally-applied voltage Va changes. For example, carriers are generated when there is damage, etc., in the semiconductor layer 10. In such a case, inversion occurs; and the C-V characteristic has a valley-like configuration.

Compared to the case shown in FIG. 8A where the flat band voltage Vfb is not controlled appropriately, the flat band voltage Vfb shifts in the positive direction in the case shown in FIG. 8B where the flat band voltage Vfb is controlled appropriately.

In such a case, the forming is performed by applying a negative voltage to the conductive layer 20. By appropriately controlling the flat band voltage Vfb as shown in FIG. 8B, the effective forming voltage Vf applied to the resistance change layer 15 is larger than that of the case shown in FIG. 8A where the flat band voltage Vfb is not controlled appropriately.

Thereby, the decrease of the effective forming voltage Vf applied to the resistance change layer 15 is suppressed. Thereby, the forming voltage Vf0 can be reduced while suppressing the fluctuation of the forming voltage.

Thus, in the embodiment, the semiconductor layer 10 is the n type; and the depletion layer is formed. Also, a configuration in which the C-V characteristic has a valley-like configuration is applied. Then, the forming is performed by applying the negative voltage to the conductive layer 20. Such forming is performed after shifting the flat band voltage Vfb in the positive direction.

To cause the shift in the positive direction, for example, the negative fixed charge 16 (e.g., nitrogen, etc.) is disposed in the resistance change layer 15.

The work function of the semiconductor layer 10 and the work function of the conductive layer 20 may be set to cause the shift in the positive direction.

According to the embodiment, a nonvolatile memory device having uniform characteristics for which a stable initialization at a low voltage is possible can be provided.

### Fourth Embodiment

The memory unit 25 (the semiconductor layer 10, the conductive layer 20, and the resistance change layer 15) are provided also in a nonvolatile memory device according to the embodiment. In the embodiment, the semiconductor layer 10 may be the p type. In the embodiment, the configuration described in regard to the nonvolatile memory device 110 is applicable to the semiconductor layer 10, the conductive layer 20, and the resistance change layer 15.

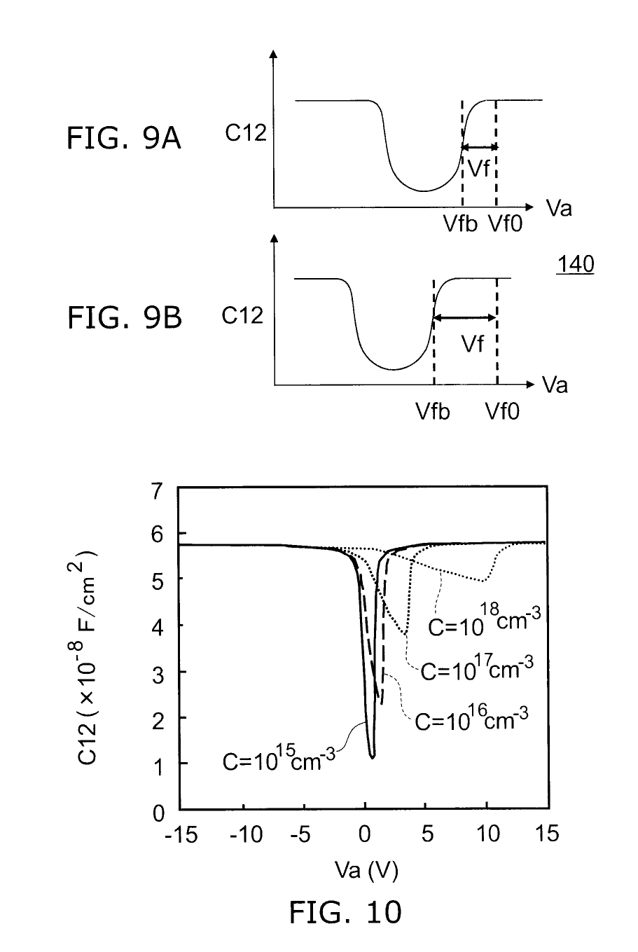

FIG. 9A and FIG. 9B are graphs showing characteristics of the nonvolatile memory device.

FIG. 9A shows the characteristic of an element in which the depletion layer is formed and the flat band voltage Vfb is not controlled appropriately. FIG. 9B shows the characteristic of an element in which the depletion layer is formed and the flat band voltage Vfb is controlled appropriately. FIG. 9B corresponds to the nonvolatile memory device 140 (of which the configuration is not shown) according to the embodiment.

In the example as well, as shown in FIG. 9A and FIG. 9B, inversion occurs and the electrostatic capacitance C12 changes in a valley-like configuration as the externally-applied voltage Va changes. For example, carriers are generated when there is damage, etc., in the semiconductor layer 10.

Compared to the case shown in FIG. 9A where the flat band voltage Vfb is not controlled appropriately, the flat band voltage Vfb shifts in the negative direction in the case shown in FIG. 9B where the flat band voltage Vfb is controlled appropriately.

In such a case, the forming is performed by applying a positive voltage to the conductive layer 20. By appropriately controlling the flat band voltage Vfb as shown in FIG. 9B, the effective forming voltage Vf applied to the resistance change layer 15 is larger than that of the case shown in FIG. 9A where the flat band voltage Vfb is not controlled appropriately.

Thereby, the decrease of the effective forming voltage Vf applied to the resistance change layer 15 is suppressed. Thereby, the forming voltage Vf0 can be reduced while suppressing the fluctuation of the forming voltage.

Thus, in the embodiment, the semiconductor layer 10 is the p type; and the depletion layer is formed. Also, a configuration in which the C-V characteristic has a valley-like configuration is applied. Then, the forming is performed by applying the positive voltage to the conductive layer 20. Such forming is performed after shifting the flat band voltage Vfb in the negative direction.

To cause the shift in the negative direction, for example, the positive fixed charge 16 (e.g., Al) is disposed in the resistance change layer 15. The fixed charge 16 may include a lanthanoid. Namely, the fixed charge 16 may include at least one selected from the group consisting of La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium).

The chemical element recited above is diffused into the resistance change layer 15 by, for example, causing the chemical element recited above to contact the resistance change layer 15 and by, for example, thermal diffusion by heating. Thereby, the fixed charge 16a recited above can be disposed inside the resistance change layer 15.

To cause the shift in the negative direction, for example, the interface portion 17f including the prescribed dipole 17 is provided. Specifically, the interface portion 17f including at least one selected from hafnium oxide (HfOₓ), aluminum oxide (AlOₓ), magnesium oxide (MgOₓ), launthanum oxide (LaOₓ), cerium oxide (CeOₓ), praseodymium oxide (PrOₓ), neodymium oxide (NdOₓ), promethium oxide (PmOₓ), samarium oxide(SmOₓ), europium oxide (EuOₓ), gadolinium oxide (GdOₓ), terbium oxide (TbOₓ), dysprosium oxide (DyOₓ), holmium oxide(HoOₓ), erbium oxide (ErOₓ), thulium oxide (TmOₓ), ytterbium oxide (YbOₓ), and lutetium oxide (LuOₓ) is provided.

The work function of the semiconductor layer 10 and the work function of the conductive layer 20 may be set to cause the shift in the negative direction.

According to the embodiment, a nonvolatile memory device having uniform characteristics for which a stable initialization at a low voltage is possible can be provided.

Examples of characteristics of the nonvolatile memory device according to the embodiment will now be described.

In the following example, the semiconductor layer 10 includes p-type polysilicon. The resistance change layer 15 includes HfO₂. In this case, the relative dielectric constant of the resistance change layer 15 is about 20. The thickness of the resistance change layer 15 is 3 nm.

FIG. 10 is a graph showing characteristics of the nonvolatile memory device according to the embodiment.

FIG. 10 shows the relationship between the externally-applied voltage Va and the electrostatic capacitance C12 of the nonvolatile memory device. This drawing shows the characteristics in the case where an impurity concentration C (a p-type impurity concentration) of the semiconductor layer 10 is 1×10¹⁵ cm⁻³, 1×10¹⁶ cm⁻³, 1×10¹⁷ cm⁻³, and 1×10¹⁸ cm⁻³. In the example, the C-V characteristic has a valley-like configuration.

As shown in FIG. 10, the electrostatic capacitance C12 changes with respect to the externally-applied voltage Va. Therefore, it can be seen that the depletion layer is formed in the element.

It can be seen from FIG. 10 that the change of the C-V characteristic is large when the impurity concentration C of the semiconductor layer 10 is low.

In the embodiment, the impurity concentration C of the semiconductor layer 10 is set to be less than 1×10¹⁹ cm⁻³. The impurity concentration C may be 1×10¹⁸ cm⁻³ or less. It is favorable for the impurity concentration C to be 1×10¹⁷ cm⁻³ or less. It is more favorable for the impurity concentration C to be 1×10¹⁶ cm⁻³ or less.

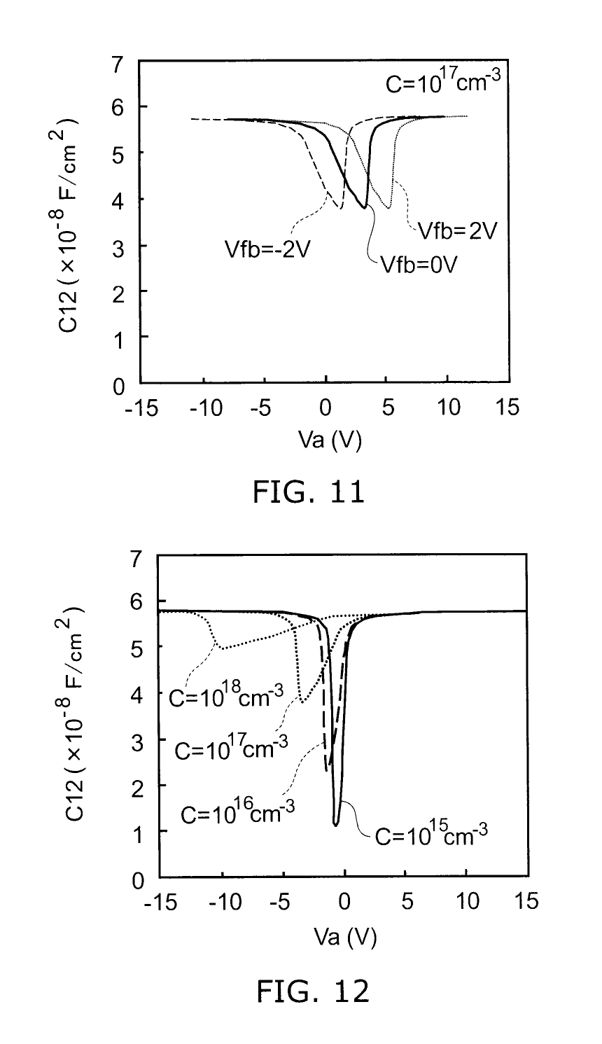

FIG. 11 is a graph showing characteristics of the nonvolatile memory device according to the embodiment.

FIG. 11 shows the change of the C-V characteristic when the flat band voltage Vfb is changed. In the example, the impurity concentration C of the semiconductor layer 10 is 1×10¹⁷ cm⁻³.

As shown in FIG. 11, the C-V characteristic shifts to the negative side when the flat band voltage Vfb is controlled to be a negative voltage (in the example, −2 V). The C-V characteristic shifts to the positive side when the flat band voltage Vfb is controlled to be a positive voltage (in the example, 2 V).

By utilizing such characteristics, the decrease of the voltage applied to the resistance change layer 15 in the forming can be suppressed.

In the following example, the semiconductor layer 10 includes n-type polysilicon. The resistance change layer 15 includes HfO₂. The thickness of the resistance change layer 15 is 3 nm.

FIG. 12 is a graph showing characteristics of the nonvolatile memory device according to the embodiment.

FIG. 12 shows the relationship between the externally-applied voltage Va and the electrostatic capacitance C12 of the nonvolatile memory device.

In the case where the semiconductor layer 1 is the n type as shown in FIG. 12, the characteristics of the case of the p-type (FIG. 11) are inverted at 0 V.

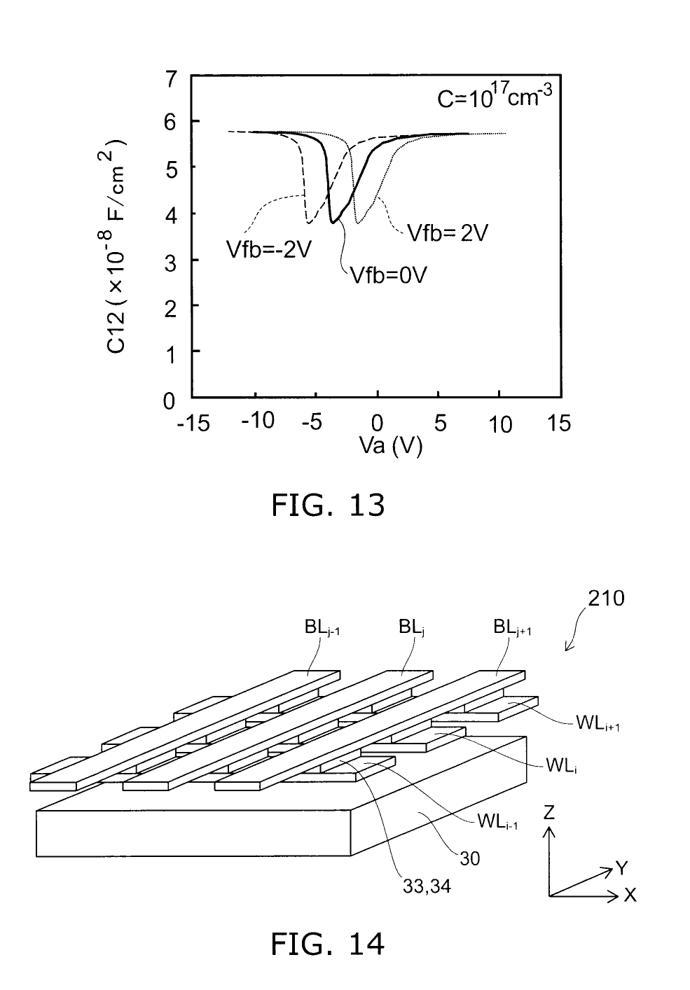

FIG. 13 is a graph showing characteristics of the nonvolatile memory device according to the embodiment.

FIG. 13 shows the change of the C-V characteristic when the flat band voltage Vfb is changed in the case where the semiconductor layer 10 is the n type. In the example, the impurity concentration C of the semiconductor layer 10 is 1×10¹⁷ cm⁻³.

As shown in FIG. 13, the C-V characteristic shifts to the negative side when the flat band voltage Vfb is controlled to be a negative voltage (in the example, −2 V). The C-V characteristic shifts to the positive side when the flat band voltage Vfb is controlled to be a positive voltage (in the example, 2 V).

By utilizing such characteristics, the decrease of the voltage applied to the resistance change layer 15 in the forming can be suppressed.

### Fifth Embodiment

A nonvolatile memory device according to the embodiment has a cross-point configuration.

FIG. 14 is a schematic perspective view showing the nonvolatile memory device according to the fifth embodiment.

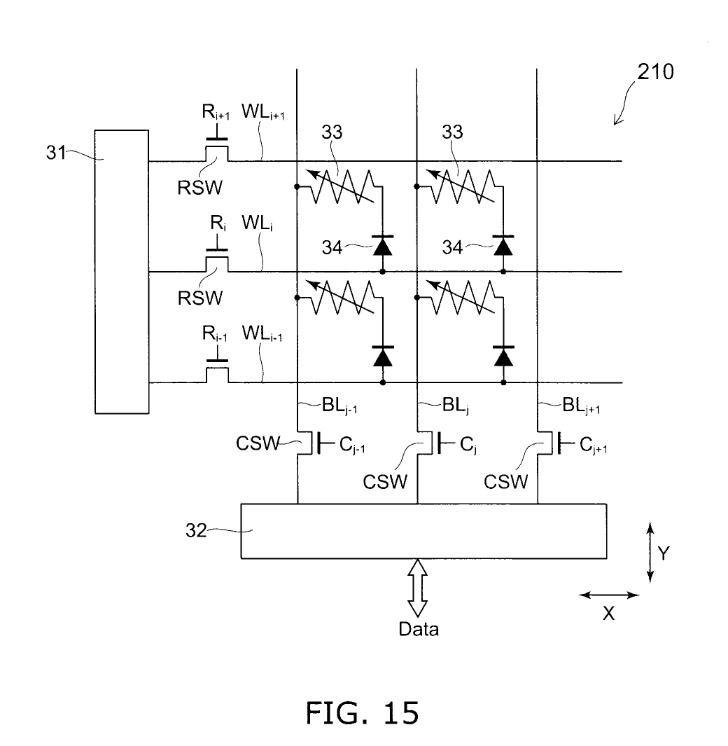

FIG. 15 is a schematic view showing the nonvolatile memory device according to the fifth embodiment.

As shown in FIG. 14 and FIG. 15, a substrate 30 is provided in the nonvolatile memory device 210 according to the embodiment. A plane parallel to a major surface of the substrate 30 is taken as an X-Y plane. One direction in the X-Y plane is taken as an X-axis direction. A direction perpendicular to the X-axis direction in the X-Y plane is taken as a Y-axis direction. A direction perpendicular to the X-axis direction and the Y-axis direction is taken as a Z-axis direction.

In the nonvolatile memory device 210, first interconnects (word lines WLᵢ₋₁, WLᵢ, and WLᵢ₊₁) are provided in line configurations on the major surface of the substrate 30 to extend in the X-axis direction. Second interconnects (bit lines BLⱼ₋₁, BLⱼ, and BLⱼ₊₁) are provided in line configurations that extend in the Y-axis direction. The second interconnects (the bit lines BLⱼ₋₁, BLⱼ, and BLⱼ₊₁) oppose the first interconnects (the word lines WLᵢ₋₁, WLᵢ, and WLᵢ₊₁).

Although the extension direction of the first interconnects is orthogonal to the extension direction of the second interconnects in the description recited above, it is sufficient for the extension direction of the first interconnects to cross (be non-parallel to) the extension direction of the second interconnects.

The index i and the index j recited above are arbitrary. In other words, the number of the first interconnects and the number of the second interconnects are arbitrary.

In this specific example, the first interconnects are the word lines; and the second interconnects are the bit lines. However, the first interconnects may be the bit lines; and the second interconnects may be the word lines. In the description hereinbelow, the first interconnects are the word lines; and the second interconnects are the bit lines.

As shown in FIG. 14 and FIG. 15, memory cells 33 are provided between the first interconnects and the second interconnects. The memory cell 33 includes the memory unit 25.

As shown in FIG. 15, for example, one end of each of the word lines WL,ᵢ₋₁, WLᵢ, and WLᵢ₊₁ is connected to a word line driver 31, which has a decoder function, via MOS transistors RSW which are selection switches. One end of each of the bit lines BLⱼ₋₁, BLⱼ, and BLⱼ₊₁ is connected to a bit line driver 32, which has a decoder function and a read-out function, via MOS transistors CSW which are selection switches.

Selection signals Rᵢ₋₁, Rᵢ, and Rᵢ₊₁ for selecting the word lines (the rows) are input to the gates of the MOS transistors RSW; and selection signals Cᵢ₋₁, Cᵢ, and Cᵢ₊₁ for selecting the bit lines (the columns) are input to the gates of the MOS transistors CSW.

The memory cells 33 are disposed at the intersections where the word lines WLᵢ₋₁, WLᵢ, and WLᵢ₊₁ and the bit lines BLⱼ₋₁, BLⱼ, and BLᵢ₊₁ oppose each other. Rectifying units 34 (rectifying elements) may be added to the memory cells 33 to prevent sneak current when programming/reading.

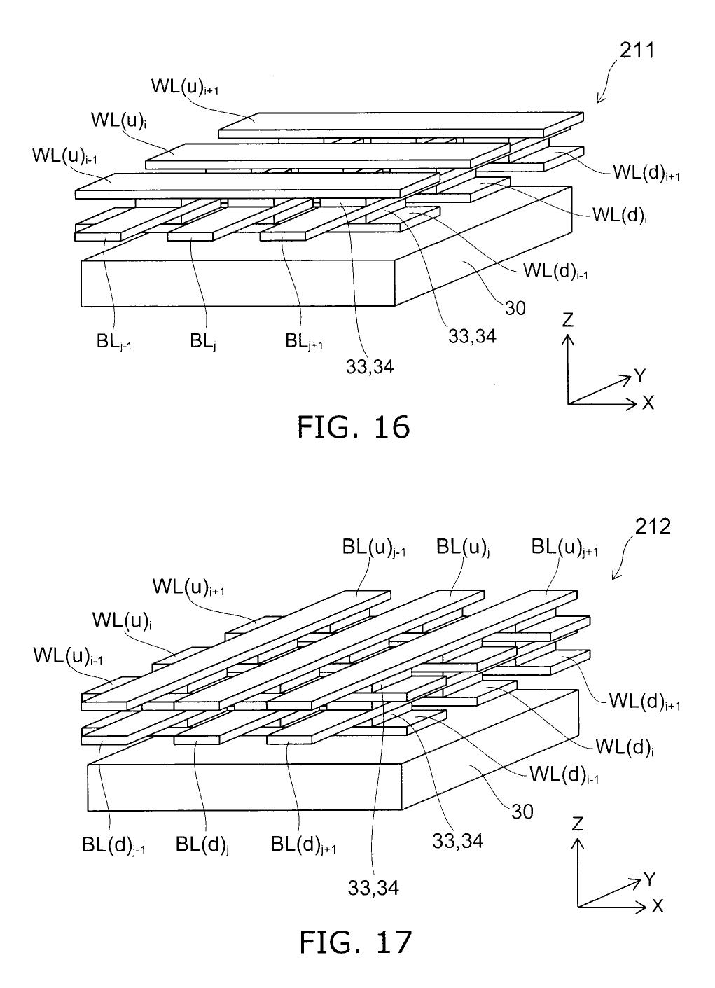

FIG. 16 and FIG. 17 are schematic perspective views showing other nonvolatile memory devices according to the fifth embodiment.

In the nonvolatile memory devices 211 and 212 according to the embodiment as shown in FIG. 16 and FIG. 17, the stacked structural body including the word line, the bit line, and the memory cell 33 provided between the word line and the bit line is multiply stacked. Thereby, a nonvolatile memory device having a three-dimensional structure is formed.

In the nonvolatile memory devices 210, 211, and 212 according to the embodiment, the word line driver 31 and the bit line driver 32, which are drive units, perform at least one selected from applying a voltage to the resistance change layer 15 via the word line WLᵢ and the bit line BLⱼ and conducting a current to the resistance change layer 15 via the word line WLᵢ and the bit line BLⱼ. Thereby, information is programmed by causing a change to occur in the resistance change layer 15. For example, the drive units program the information by causing a change to occur in the resistance change layer 15 by applying a voltage to the resistance change layer 15. Also, the information that is programmed can be read. Further, erasing can be performed.

In the nonvolatile memory devices 210, 211, and 212 according to the embodiment as well, a nonvolatile memory device having uniform characteristics can be provided.

According to the embodiments, a nonvolatile memory device having uniform characteristics for which a stable initialization at a low voltage is possible can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to the specific examples. However, the invention is not limited to these specific examples. For example, one skilled in the art may similarly practice the invention by appropriately selecting specific configurations of component included in substrates included in nonvolatile memory devices, semiconductor layers, conductive layers, resistance change layers, fixed charges, dipoles, interface portions, first interconnects, second interconnects, substrate and drivers, etc., from known art. Such practice is included in the scope of the invention to the extent that similar effects thereto are obtained.

Further, any two or more components of the specific examples may be combined within the extent of technical feasibility and are included in the scope of the embodiments to the extent that the spirit of the embodiments is included.

Moreover, all nonvolatile memory devices practicable by an appropriate design modification by one skilled in the art based on the nonvolatile memory devices described above as embodiments of the invention also are within the scope of the invention to the extent that the purport of the embodiments of the invention is included.

Furthermore, various modifications and alterations within the spirit of the invention will be readily apparent to those skilled in the art.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device, comprising:
a semiconductor layer having an impurity concentration less than 1×10¹⁹ cm⁻³;
a conductive layer; and
a resistance change layer provided between the semiconductor layer and the conductive layer, the resistance change layer including a fixed charge, the resistance change layer being reversibly transitionable between a first state and a second state by at least one selected from a current supplied via the semiconductor layer and the conductive layer and a voltage applied via the semiconductor layer and the conductive layer, a resistance of the resistance change layer in the second state being higher than a resistance of the resistance change layer in the first state.

2. The device according to claim 1, wherein
the semiconductor layer is a p type, and
the fixed charge includes nitrogen.

3. The device according to claim 1, wherein
the semiconductor layer is an n type, and
the fixed charge includes at least one selected from the group consisting of aluminum, La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium).

4. The device according to claim 1, wherein the semiconductor layer includes poly silicon.

5. The device according to claim 1, wherein an electrostatic capacitance between the semiconductor layer and the conductive layer is configured to change in accordance with a voltage between the semiconductor layer and the conductive layer.

6. The device according to claim 1, wherein a depletion layer is configured to be generated in the semiconductor layer.

7. The device according to claim 1, wherein the impurity concentration in the semiconductor layer is not more than 1×10¹⁸ cm⁻³.

8. The device according to claim 1, wherein the impurity concentration in the semiconductor layer is not more than 1×10¹⁷ cm⁻³.

9. The device according to claim 1, wherein the resistance change layer includes an oxide including at least one selected from the group consisting of Hf, Ni, Ta, Ti, W, Cu, Nb, Mn, Fe, Zr, Al and Co.

10. The device according to claim 1, further comprising:
a first interconnect; and
a second interconnect,
the semiconductor layer, the conductive layer and the resistance change layer being provided between the first interconnect and the second interconnect.

11. A nonvolatile memory device, comprising:
a semiconductor layer having an impurity concentration less than 1×10¹⁹ cm⁻³;
a conductive layer;
a resistance change layer provided between the semiconductor layer and the conductive layer, the resistance change layer being reversibly transitionable between a first state and a second state by at least one selected from a current supplied via the semiconductor layer and the conductive layer and a voltage applied via the semiconductor layer and the conductive layer, a resistance of the resistance change layer in the second state being higher than a resistance of the resistance change layer in the first state; and
an interface portion provided between the semiconductor layer and the resistance change layer, the interface portion including a dipole.

12. The device according to claim 11, wherein
the semiconductor layer is an n type, and
the interface portion includes at least one selected from hafnium oxide, aluminum oxide, magnesium oxide launthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, and lutetium oxide.

13. The device according to claim 11, wherein the semiconductor layer includes a poly silicon.

14. The device according to claim 11, wherein an electrostatic capacitance between the semiconductor layer and the conductive layer is configured to change in accordance with a voltage between the semiconductor layer and the conductive layer.

15. The device according to claim 11, wherein a depletion layer is configured to be generated in the semiconductor layer.

16. The device according to claim 11, wherein the impurity concentration in the semiconductor layer is not more than 1×10¹⁸ cm⁻³.

17. The device according to claim 11, wherein the resistance change layer may includes an oxide including at least one selected from the group consisting of Hf, Ni, Ta, Ti, W, Cu, Nb, Mn, Fe, Zr, Al and Co.

18. The device according to claim 11, further comprising:
a first interconnect; and
a second interconnect,
the semiconductor layer, the conductive layer and the resistance change layer being provided between the first interconnect and the second interconnect.
